(19) United States
(12) Patent Application Publication
(10) Pub. No.: US 2015/0206960 A1
(43) Pub. Date: Jul. 23, 2015

(54) SEMICONDUCTOR DEVICE

(71) Applicants: Yasuhiro HIRABAYASHI, Toyota-shi (JP); Satoru MACHIDA, Nagakute-shi (JP); Yusuke YAMASHITA, Nagoya-shi (JP)

(72) Inventors: Yasuhiro HIRABAYASHI, Toyota-shi (JP); Satoru MACHIDA, Nagakute-shi (JP); Yusuke YAMASHITA, Nagoya-shi (JP)

(73) Assignee: TOYOTA JIDOSHA KABUSHIKI KAISHA, Toyota-shi (JP)

(21) Appl. No.: 14/564,209

(22) Filed: Dec. 9, 2014

(30) Foreign Application Priority Data
Jan. 20, 2014 (JP) 2014-007713

(51) Int. Cl. H01L 29/739; H01L 29/423; H01L 27/06

(52) U.S. Cl. CPC H01L 29/7397; H01L 27/0635; H01L 29/4236

(57) ABSTRACT

A semiconductor device 1 in which an IGBT region 2 and a diode region 3 adjoining each other are formed on a same substrate 4 is presented. The semiconductor device 1 is provided with a plurality of first gate trenches 11 extending abreast in a first direction in the IGBT region 2 and a plurality of second gate trenches 12 extending abreast in a second direction intersecting the first direction. The first gate trenches 11 and the second gate trenches 12 are not in contact with each other.

### CROSS-REFERENCE TO RELATED APPLICATION

This application claims priority to Japanese Patent Application No. 2014-007713 filed on Jan. 20, 2014, the contents of which are hereby incorporated by reference into the present application.

### TECHNICAL FIELD

A technology disclosed herein relates to a semiconductor device including gate trenches.

### DESCRIPTION OF RELATED ART

Patent Literature 1 (Japanese Patent Application Publication No, 2003-529209) discloses a semiconductor device including a plurality of gate trenches. In the semiconductor device of Patent Literature 1, the plurality of gate trenches extends in directions intersecting each other. This semiconductor device includes a plurality of gate trenches extending in a longitudinal direction as viewed in planar view and a plurality of gate trenches extending in a transverse direction so as to orthogonally intersect the plurality of gate trenches extending in the longitudinal direction. A p-type deep semiconductor region is formed between adjoining gate trenches to obtain higher withstand voltage.

### BRIEF SUMMARY OF INVENTION

In the semiconductor device of Patent Literature 1, the gate trenches extending in the longitudinal direction and the gate trenches extending in the transverse direction are in contact with each other at their intersections. In such a configuration, the trenches may be deeper at the intersections thereof the gate trenches extending in the longitudinal direction and the gate trenches extending in the transverse direction than in other parts thereof. This may undesirably cause electric field concentration near the deeper intersections and thus undesirably decrease the withstand voltage of the semiconductor device. The present specification therefore intends s to provide a semiconductor device configured to have the higher withstand voltage and enhance switching characteristics.

The present speciation discloses a semiconductor device in which an IGBT region and a diode region adjoining each other are formed on a same substrate. The semiconductor device comprises a plurality of first gate trenches extending abreast in a first direction in the IGBT region and a plurality of second gate trenches extending abreast in a second direction intersecting the first direction. The first gate trenches and the second gate trenches are not in contact with each other.

In such a configuration, the first gate trenches and the second gate trenches are not in contact with each other such that there is no portion in which the first gate trenches and the second gate trenches intersect each other. This configuration makes it possible to prevent the trenches from becoming locally deeper due to the first gate trenches and the second gate trenches intersecting each other. This in turn makes it possible to prevent local electric field concentration, thus preventing a decrease in the withstand voltage of the semiconductor device. Further, since the decrease in the withstand voltage can be prevented here, it is not necessary to form p-type deep semiconductor region between adjoining gate trenches to obtain higher withstand voltage as in the technology of Patent Literature 1. Accordingly, no extra carriers (holes) are injected into diode region from the p-type semiconductor region such that annihilation time of carriers (holes) during reverse recovery of the diode can be shortened. This in turn makes it possible to inhibit switching loss during the reverse recovery. For the reasons stated above, the semiconductor device disclosed herein can have both the higher withstand voltage and the enhanced switching characteristics.

### BRIEF DESCRIPTION OF DRAWINGS

FIG. 1 is a cross-sectional view of a main part of a semiconductor device according to an embodiment;

FIG. 2 is a perspective view of the main part of the semiconductor device according to the embodiment;

FIG. 3 is a plan view of the main part of the semiconductor device according to the embodiment;

FIG. 4 is a plan view schematically showing an arrangement of gate trenches according to the embodiment;

FIG. 5 is a plan view schematically showing an arrangement of gate trenches according to an embodiment;

FIG. 6 is a plan view schematically showing an arrangement of gate trenches according to an embodiment;

FIG. 7 is a plan view schematically showing an arrangement of gate trenches according to an embodiment;

FIG. 8 is a cross-sectional view of a main part of a semiconductor device according to an embodiment; and

FIG. 9 is a perspective view of a main part of a semiconductor device according to an embodiment.

### DETAILED DESCRIPTION OF INVENTION

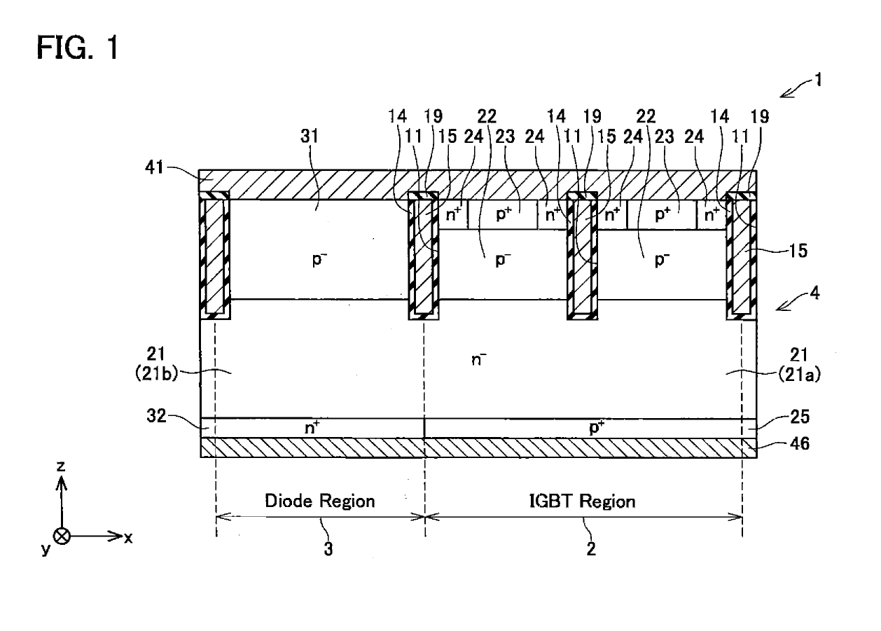

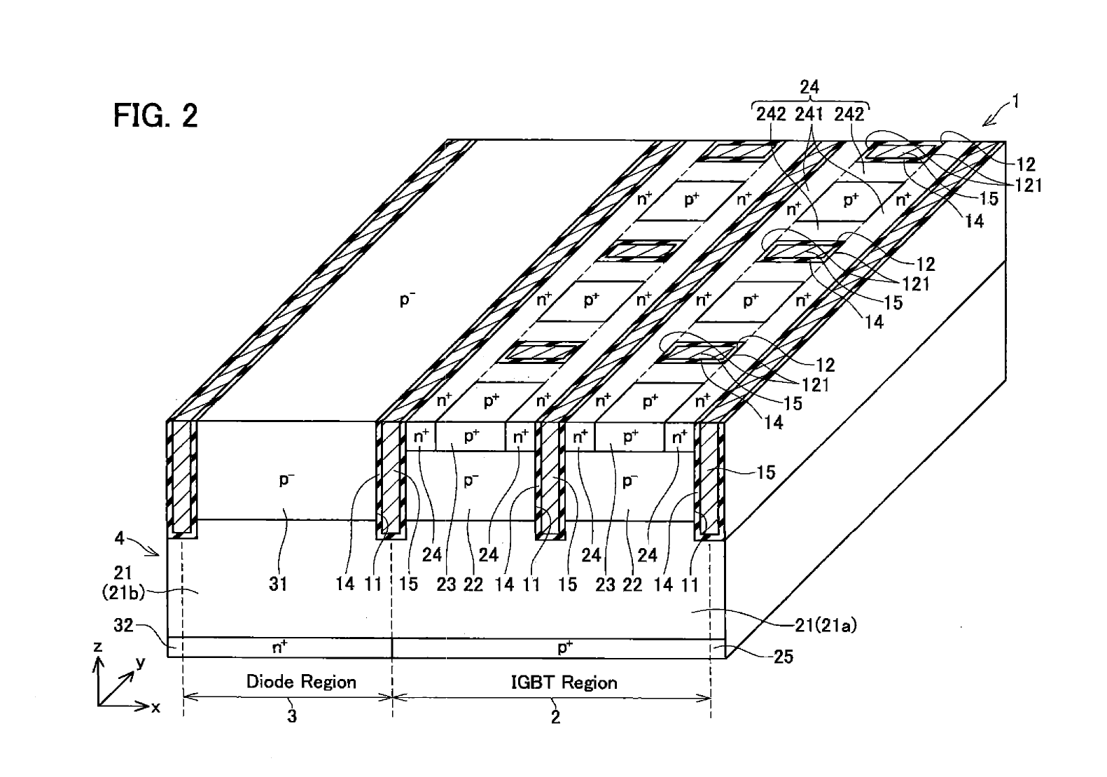

Embodiments are described below with reference to accompanying drawings. In the following description, hatching on some of configurations shown in the drawings is omitted for viewability of the drawings. A semiconductor device according to an embodiment is an RC-IGBT (Reverse Conducting Insulated Gate Bipolar Transistor) and has a function as an IGBT (Insulated Gate Bipolar Transistor) and a function as an FWD (Free Wheeling Diode). The IGBT and the FWD are arranged in a reverse-parallel state. As shown in FIGS. 1 and 2, a semiconductor device 1 includes a semiconductor substrate 4, an upper-surface-side common electrode 41 disposed on a upper surface side of the semiconductor substrate 4, and a lower-surface-side common electrode 46 disposed on a lower surface side of the semiconductor substrate 4 (Note that FIG. 2 omits to show the upper-surface-side common electrode 41 and the lower-surface-side common electrode 46.). Further, the semiconductor device 1 includes an IGBT region 2 functioning as the IGBT and a diode region 3 functioning as the FWD. The IGBT region 2 and the diode region 3 adjoining each other are formed on the same semiconductor substrate 4, whereby the semiconductor device 1, which is a reverse conduction type, is formed.

The semiconductor substrate 4 is made, for example, of silicon (Si) or the like with impurities injected thereinto. In the IGBT region 2 of the semiconductor substrate 4, a plurality of first gate trenches 11 and a plurality of second gate trenches 12 are formed (Note that FIG. 1 does not show the second gate trenches 12.). Further, in the IGBT region 2, emitter layers 24, contact layers 23, body layers 22, a drift layer 21 (IGBT drift layer 21a) and a collector layer 25 are formed in this order from an upper surface side. In the diode region 3 of the semiconductor substrate 4, an anode layer 31, the drift layer 21 (diode drift layer 21b) and a cathode layer 32 are formed in this order from the upper surface side.

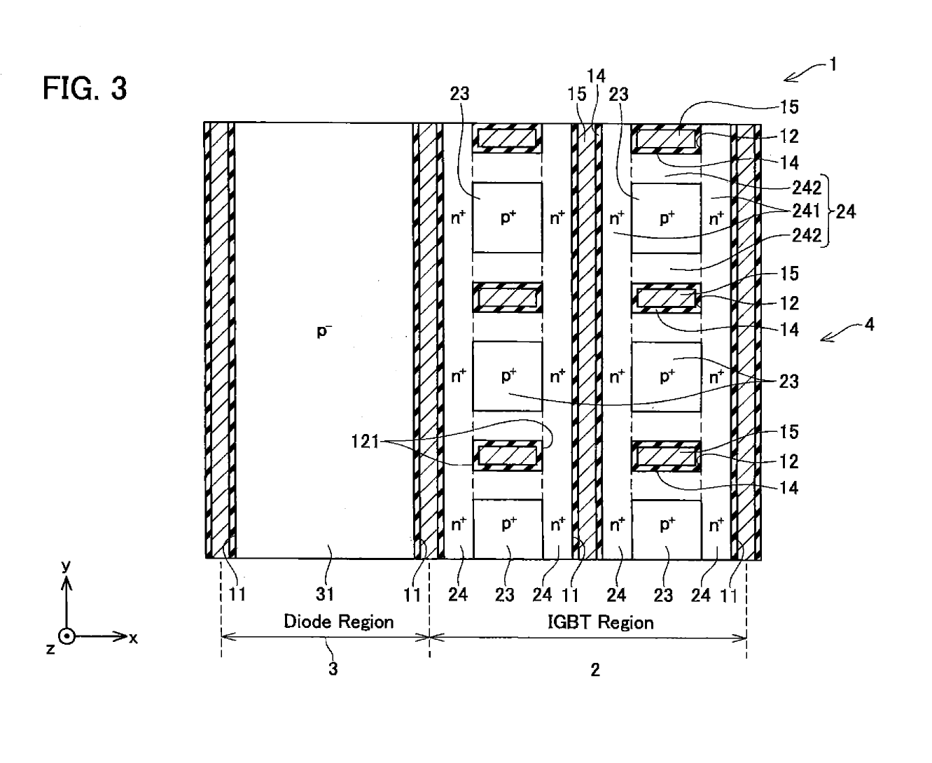

The plurality of first gate trenches 11 is placed abreast at intervals. As shown in FIG. 1, the plurality of first gate trenches 11 is placed abreast in an x direction. Further, as shown in FIG. 2, each of the first gate trenches 11 extends linearly in a y direction. The plurality of first gate trenches 11 extends in alignment with one another along one direction (y direction). Further, as shown in FIG. 3, the plurality of first gate trenches 11 extends parallel to one another as viewed in planar view.

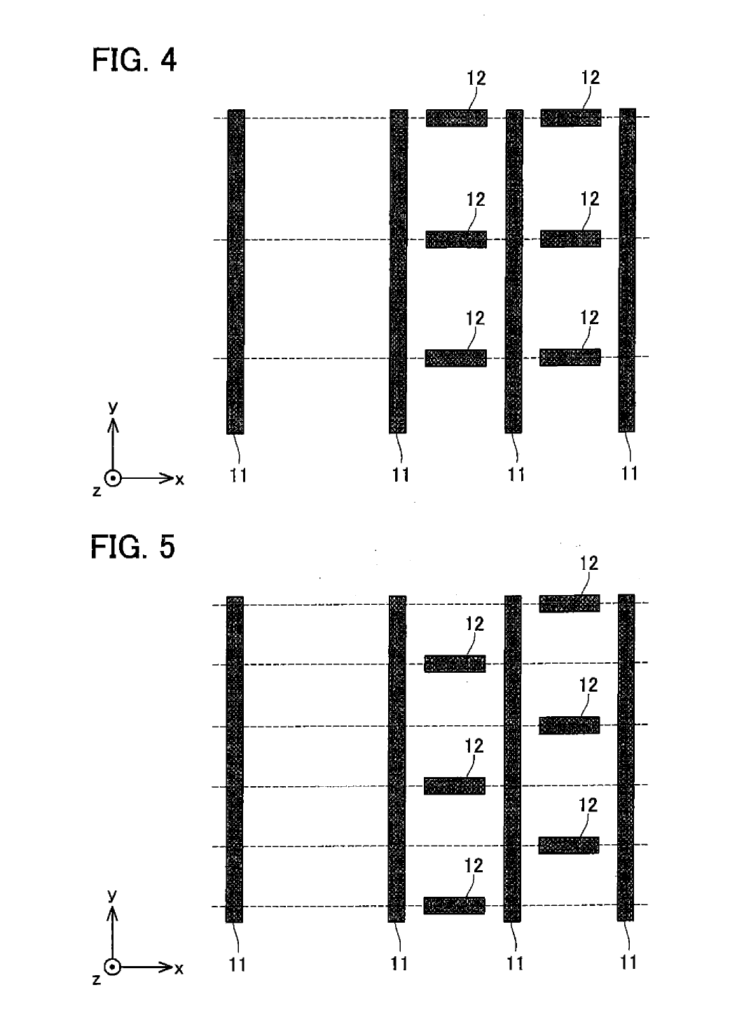

The plurality of second gate trenches 12 is placed abreast at intervals. As shown in FIG. 3, the plurality of second gate trenches 12 is placed abreast in the y direction. Further, each of the second gate trenches 12 extends linearly in the x direction. The plurality of second gate trenches 12 extend in alignment with one another along one direction (x direction). The plurality of second gate trenches 12 extends parallel to one another as viewed in the planar view. Further, as schematically shown in FIG. 4, the plurality of second gate trenches 12 aligned in the x direction is placed so that their positions in the y direction to be the same.

A length of each of the first gate trenches 11 in a lengthwise direction thereof (i.e. the length of each of the first gate trenches 11 in the y direction) is longer than a length of each of the second gate trenches 12 in the lengthwise direction thereof (i.e. the length of each of the second gate trenches 12 in the x direction). In other words, the length of each of the second gate trenches 12 in the lengthwise direction thereof is shorter than the length of each of the first gate trenches 11 in the lengthwise direction thereof The first gate trenches 11 and the second gate trenches 12 extend in directions intersecting each other. In other words, the lengthwise direction of the first gate trenches 11 and the lengthwise direction of the second gate trenches 12 intersect each other. In an example shown in FIG. 3, the first gate trenches 11 and the second gate trenches 12 extend in directions orthogonal to each other. Further, the first gate trenches 11 and the second gate trenches 12 are not in contact with each other but are separate from each other. A semiconductor layer is interposed between the first gate trenches 11 and the second gate trenches 12. Since the first gate trenches 11 and the second gate trenches 12 are separate from each other, there are no portions where they intersect each other. The first gate trenches 11 and the second gate trenches 12 are each formed by etching.

In the direction (x direction) in which the plurality of first gate trenches 11 is placed abreast, each of the second gate trenches 12 is disposed between adjoining first gate trenches 11. Lengthwise ends 121 of the second gate trenches 12 are separate from the first gate trenches 11. In the direction (y direction) in which the plurality of second gate trenches 12 is placed abreast, no first gate trench 11 is disposed between adjoining second gate trenches 12. In the direction (x direction) in which the second gate trenches 12 extend, each of the first gate trenches 11 is disposed between adjoining second gate trenches 12. The first gate trenches 11 and the second gate trenches 12 are in a form of a ladder as viewed in the planar view of FIG. 3.

The first gate trenches 11 and the second gate trenches 12 are formed deeper than the body layers 22 in a depth direction (z direction). The first gate trenches 11 and the second gate trenches 12 penetrate the body layers 22 reach inside the drift layer 21. Electric field concentration occurs near bottoms of the first gate trenches 11 and bottoms of the second gate trenches 12.

Gate insulating films 14 are formed on inner surfaces of the first gate trenches 11 and inner surfaces of the second gate trenches 12, respectively. The gate insulating films 14 cover side surfaces and bottom surfaces of the first gate trenches 11 and side surfaces and bottom surfaces of the second gate trenches 12. Gate electrodes 15 are formed respectively in inner parts of the first gate trenches 11 and inner parts of the second gate trenches 12. The gate electrodes 15 are covered by the insulating films 14. The gate electrodes 15 are filled with the first gate trenches 11 and the second gate trenches 12 respectively. Interlayer insulating films 19 are disposed on the gate electrodes 15. The interlayer insulating films 19 insulate the gate electrodes 15 from the upper-surface-side common electrode 41.

The emitter layers 24 are formed in such an area as to be exposed on the upper surface side of the semiconductor substrate 4. The emitter layers 24 are of n type, and have a high impurity concentration. In the present embodiment, the emitter layers 24 have an impurity concentration of about 1×10¹⁸ to 1×10²⁰ [cm ⁻³]. The emitter layers 24 are ohmically connected to the upper-surface-side common electrode 41. The emitter layers 24 are formed in such an area as to be in contact with the gate insulating films 14. The emitter layers 24 adjoin the first gate trenches 11 or the second gate trenches 12. Each emitter layer 24 is divided into first emitter layers 241 and second emitter layers 242. The first emitter layers 241 and the second emitter layers 242 are formed integrally with each other. The first emitter layers 241 are formed for the first gate trenches 11. The first emitter layers 241 are formed so as to extend along the first gate trenches 11 and are in contact with the first gate trenches 11. The first emitter layers 241 continuously extend along the direction (y direction) in which the first gate trenches 11 extend. The second emitter layers 242 are formed for the second gate trenches 12. The second emitter layers 242 are formed so as to extend along the second gate trenches 12 and are in contact with the second gate trenches 12. The second emitter layers 242 continuously extend along the direction (x direction) in which the second gate trenches 12 extend.

The contact layers 23 are formed in shapes of islands in such an area as to be exposed on the upper surface side of the semiconductor substrate 4. The contact layers 23 are formed in areas as to be surrounded by the emitter layers 24. The contact layers 23 are of p type, and have a high impurity concentration. In the present embodiment, the contact layers 23 have an impurity concentration of about 1×10¹⁷ to 1×10²⁰ [cm⁻³]. The contact layers 23 are ohmically connected to the upper-surface-side common electrode 41. Further, the contact layers 23 are in contact with the body layers 22.

The body layers 22 are formed on a lower side of the emitter layers 24 and a lower side of the contact layers 23. The body layers 22 are formed in areas as to be lower than lower ends of the first gate trenches 11 and lower ends of the second gate trenches 12. The body layers 22 is of p type, and have a lower impurity concentration than the contact layer 23 does. In the present embodiment, the body layers 22 have an impurity concentration of about 1×10¹⁶ to 1×10¹⁹ [cm⁻]. The body layers 22 separate the emitter layers 24 from the IGBT drift layer 21a. The body layers 22 are formed so as to adjoin the first gate trenches 11 and the second gate trenches 12. The body layers 22 are in contact with the gate insulating films 14.

The drift layer 21 is divided into the IGBT drift layer 21a and the diode drift layer 21b. The IGBT drift layer 21a is located in the IGBT region 2 and the diode drift layer 21b is located in the diode region 3. The IGBT drift layer 21a and the diode drift layer 21b are formed integrally with each other and are continuous with each other. The IGBT drift layer 21a and the diode drift layer 21b are of n type, and have approximately equal impurity concentrations of about 1×10¹² to 1×10¹⁵ [cm⁻³]. The IGBT drift layer 21a is formed on a lower side of the body layer 22, the Bottoms of the first gate trenches 11 and bottoms of the second gate trenches 12 are formed in the drift layer 21.

The collector layer 25 is formed on a lower side of the IGBT drift layer 21a. The collector layer 25 is formed in such an area as to be exposed on the lower surface side of the semiconductor substrate 4. The collector layer 25 is of p type, and has a high impurity concentration. In the present embodiment, the collector layer 25 has an impurity concentration of 1×10¹⁷ to 1×10²⁰ [cm⁻³]. The collector layer 25 is ohmically connected to the lower-surface-side common electrode 46.

The anode layer 31 is exposed on the upper surface side of the semiconductor substrate 4. The anode layer 31 is of a p type, and has a low impurity concentration. In the present embodiment, the anode layer 31 has an impurity concentration of 1×10¹⁶ to 1×10¹⁹ [cm⁻³]. The anode layer 31 is ohmically connected to the upper-surface-side common electrode 41. On a lower side of the anode layer 31, the diode drift layer 21b is formed.

The cathode layer 32 is formed on a lower side of the diode drift layer 21b. The cathode layer 32 is exposed on the lower surface side of the semiconductor substrate 4. The cathode layer 32 is of an n type, and has a high impurity concentration. In the present embodiment, the cathode layer 32 has an impurity concentration of 1×10¹⁷ to 5×10²⁰ [cm⁻³].

The cathode layer 32 is ohmically connected to the lower-surface-side common electrode 46.

The upper-surface-side common electrode 41 and the lower-surface-side common electrode 46 are each made, for example, of a conducting metal such as nickel (Ni). The upper-surface-side common electrode 41 works as an emitter electrode for the emitter layers 24 and as an anode electrode for the anode layer 31. The lower-surface-side common electrode 46 works as a collector electrode for the collector layer 25 and as a cathode electrode for the cathode layer 32. The upper-surface-side common electrode 41, the lower-surface-side common electrode 46 and the gate electrodes 15 are each connected to a power supply (not illustrated).

Next, operation of the semiconductor device 1 thus configured is described. First, when potential applied to the gate electrodes 15 in the first gate trenches 11 and in the second gate trenches 12 is ON potential, channels are formed in areas in the body layers 22 that are in contact with the first gate trenches 11 and the second gate trenches 12, respectively. Further, when a voltage (i.e. a forward voltage to the IGBT) that renders the lower surface side (collector layer 25 side) positive is applied between the upper-surface-side common electrode 41 and the lower-surface-side common electrode 46, the IGBT is turned on. This causes electrons to flow from the upper-surface-side common electrode 41 to the lower-surface-side common electrode 46 via the emitter layers 24, the channels formed in the body layers 22, the IGBT drift layer 21a and the collector layer 25. Further, holes are caused to flow from the lower-surface-side common electrode 46 to the upper-surface-side common electrode 41 via the collector layer 25, the IGBT drift layer 21 a, the body layers 22 and the contact layers 23.

Next, when the potential applied to the gate electrodes 15 is switched from the ON potential to OFF potential, the channels formed in the body layer 22 are annihilated so that the IGBT is turned off. Further, when a voltage (i.e. a forward voltage to the FWD) that renders the upper surface side (anode layer 31 side) positive is applied between the upper-surface-side common electrode 41 and the lower-surface-side common electrode 46, the FWD is turned on. This causes holes to flow from the upper-surface-side common electrode 41 to the lower-surface-side common electrode 46 via the anode layer 31, the diode drift layer 21b and the cathode layer 32. Further, electrons are caused to flow from the lower-surface-side common electrode 46 to the upper-surface-side common electrode 41 via the cathode layer 32, the diode drift layer 21b and the anode layer 31.

When the FWD is on, a portion in the body layer 22 of the IGBT region 2 that is close to the diode region 3, the IGBT drift layer 21a and a portion in the cathode layer 32 of the diode region 3 that is close to the IGBT region 2 may act as a parasitic diode. In this case, carriers (holes) injected from the body layer 22 side into the IGBT drift layer 21a move toward the cathode layer 32 via the diode drift layer 21b. At this time, the carriers (holes) may accumulate in the diode drift layer 21b.

Next, the FWD performs a reverse recovery operation when the voltage of the FWD is switched and a voltage (i.e. a backward voltage to the FWD) that renders the lower surface side (cathode layer 32 side) positive is applied between the upper-surface-side common electrode 41 and the lower-surface-side common electrode 46. That is, the holes that were present in the diode drift layer 21b during the forward voltage application are discharged into the upper-surface-side common electrode 41 via the anode layer 31 and the electrons that were present in the diode drift layer 21b during the forward voltage application are discharged into the lower-surface-side common electrode 46 via the cathode layer 32. This causes a reverse current to flow through the diode region 3. As mentioned above, the semiconductor device 1 operates by the IGBT and the diode thus switching between ON and OFF.

As is evident from the above descriptions, in the semiconductor device 1 according to the embodiment, the first gate trenches 11 extending in a first direction and the second gate trenches 12 extending in a second direction intersecting the first direction are formed. For this reason, a channel density of the IGBT is high such that the ON potential of the IGBT is reduced. Further, the first gate trenches 11 and the second gate trenches 12 are not in contact with each other such that there are no places where the first gate trenches 11 and the second gate trenches 12 intersect each other. This configuration makes it possible to prevent the trenches from becoming locally deeper due to the first gate trenches 11 and the second gate trenches 12 intersecting each other. This configuration accordingly makes it possible to prevent a decrease in the withstand voltage of the semiconductor device 1. Specifically, if the first gate trenches 11 and the second gate trenches 12 intersect each other, much of an etchant will enter into their intersections, for example, on an occasion of the first gate trenches 11 and the second gate trenches 12 being formed by etching, with a result that the trenches become locally deeper at those intersections. If there is any local deep portions in the trenches, the trenches undesirably cause concentration of electric fields near the deep portions and thus undesirably decrease the withstand voltage of the trench portions. Such concentration of electric fields may be inhibited by forming a p-type deep semiconductor region (a region formed by making a part of the body region deeper) as in Patent Literature 1. However, a formation of the p-type deep semiconductor region makes it easier for electric current to flow through the aforementioned parasitic diode, thus making it easier for extra holes to be supplied to the diode region 3. This makes it easier for a reverse current to flow during the reverse recovery operation of the FWD. For these reasons, it is difficult to employ the configuration of Patent Literature 1 in an RC-IGBT. Contrary to this, in the semiconductor device 1 according to the embodiment, the first gate trenches 11 and the second gate trenches 12 are not in contact with each other; therefore, the trenches can be prevented from becoming locally deeper. This makes it possible to prevent local concentration of the electric fields, thus making it possible to prevent the decrease in the withstand voltage. This eliminates the need to form the p-type deep semiconductor region as in the technology of Patent Literature 1. This makes it possible to inhibit the reverse current during the reverse recovery operation of the FWD, thus making it possible to inhibit switching loss. For the reasons stated above, the semiconductor device 1 according to the embodiment can have both higher withstand voltage and the enhanced switching characteristics.

Further, in the semiconductor device 1 according to the embodiment, a length of each of the first gate trenches 11 in the lengthwise direction thereof (y direction) is longer than a length of each of the second gate trenches 12 in the lengthwise direction thereof (x direction) and the first emitter layers 241 are formed so as to extend along the first gate trenches 11. Since the first gate trenches 11 are thus long, a length of the first emitter layers 241 in the lengthwise direction thereof can be freely adjusted. That is, the first emitter layers 241 can be formed with a higher degree of freedom of the length thereof This makes it possible to freely adjust the length of the first emitter layers 241 to adjust the amount of electrons that flow from the first emitter layers 241 into the channels formed in the body layers 22. This in turn makes it possible to lower ON resistance with which the IGBT is turned on, thus inhibiting stationary loss. Further, in the semiconductor device 1 according to the embodiment, the second emitter layers 242 are formed so as to extend along the second gate trenches 12. Such formation of the first emitter layers 241 and the second emitter layers 242 can further increase the amount of electrons flowing into the channels formed in the body layers 22, thus achieving a reduction of the on resistance with which the IGBT is turned on.

One embodiment has been described above; however, specific aspects of the teachings herein are not limited to those of the embodiment described above. In the embodiment described above, no gate trenches are formed in the diode region 3. However, this configuration does not imply any limitation. For example, gate trenches may be formed in the diode region 3. In this case, it is preferable in the diode region 3, too, for gate tranches extending in a first direction and gate trenches extending in a second direction intersecting the first direction not to be in contact with each other.

In the embodiment described above, the plurality of first gate trenches 11 extends parallel to one another. However, the plurality of first gate trenches 11 does not strictly need to extend parallel to one another, but need only to extend in alignment with one another in one direction. The same applies to the plurality of second gate trenches 12.

Further, in the embodiment described above, the second emitter layers 242 are formed so as to extend along the second gate trenches 12. However, the second emitter layer can be omitted,

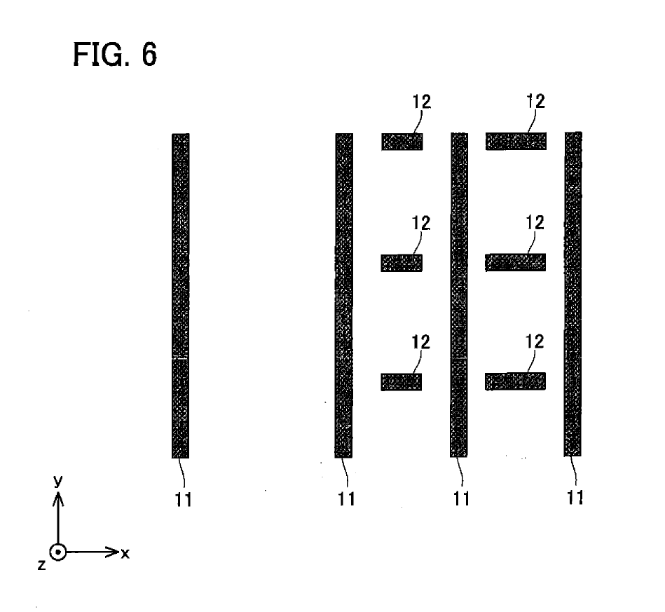

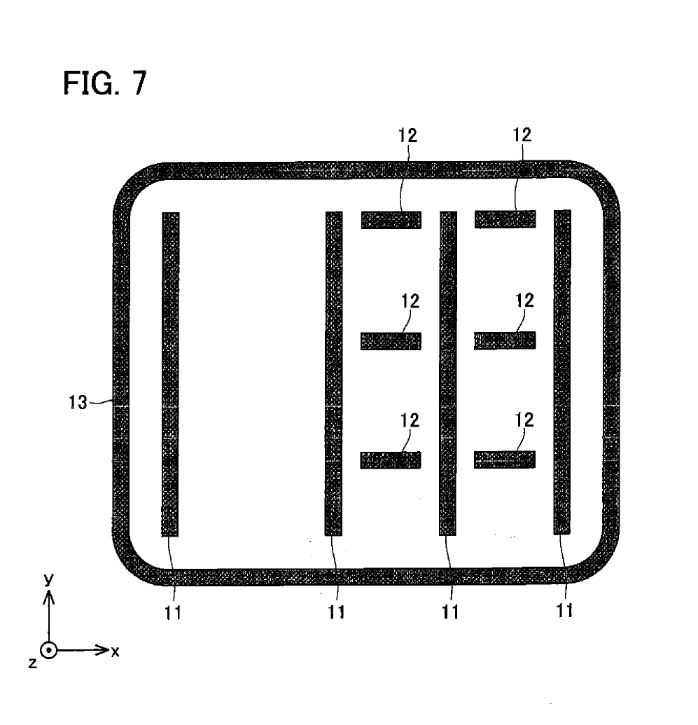

Further, the arrangement of gate trenches is not limited to that of the embodiment described above. In the embodiment described above, the plurality of second gate trenches 12 placed abreast in the x direction is placed at positions in alignment with one another in the y direction. However, this configuration does not imply any limitation. As shown in FIG. 5, the plurality of second gate trenches 12 placed abreast in the x direction may be placed at positions out of alignment with one another in the y direction. Alternatively, as shown in FIG. 6, the plurality of second gate trenches 12 placed abreast in the x direction may vary in length in the lengthwise direction thereof (x direction). Alternatively, as shown in FIG. 7, a third gate trench 13 may be disposed around the plurality of first gate trenches 11 and the plurality of second gate trenches 12. The third gate trench 13 surrounds the first gate trenches 11 and the second gate trenches 12. The third gate trench 13 is formed in a loop shape as viewed in planar view.

Further, in the embodiment described above, the ON potential is applied to the gate electrodes 15 formed in the first gate trenches 11 and in the second gate trenches 12. However, this configuration does not imply any limitation. The ON potential may be applied to the gate electrodes 15 formed either in the first gate trenches 11 or in the second gate trenches 12. For example, the ON potential may be applied to only the gate electrodes 15 formed in the first gate trenches 11. In this case, the gate electrodes 15 formed in the other gate trenches to which no ON potential is applied are in a floating state.

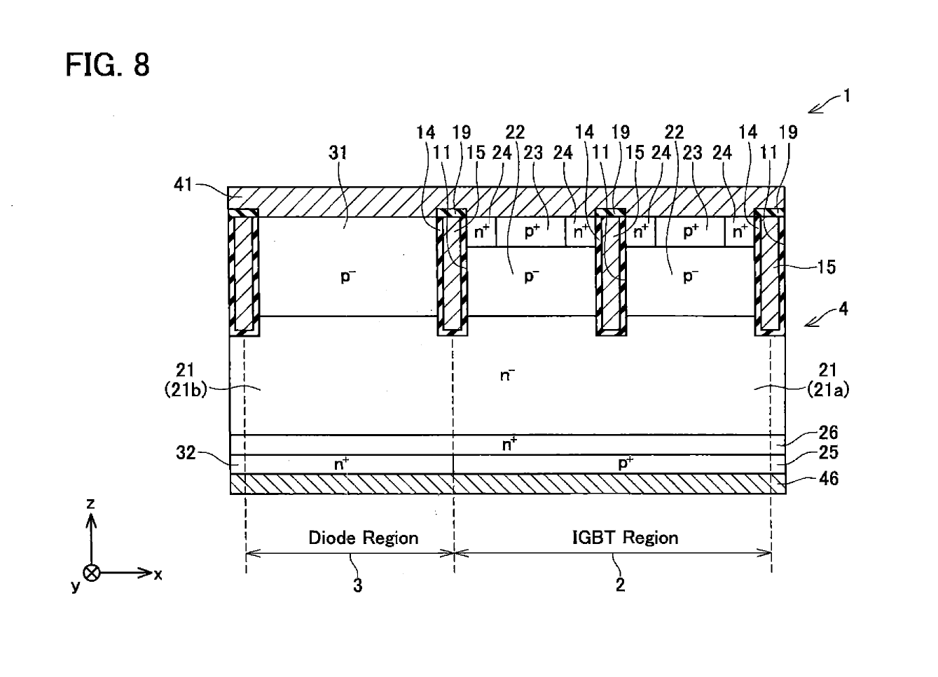

The laminated structure of the semiconductor substrate 4 is not limited to that of the embodiment described above. For example, as shown in FIG. 8, a buffer layer 26 may be formed on a lower side of the drift layer 21. The buffer layer 26 is of n type and has an impurity concentration that is higher than the impurity concentration of the drift layer 21.

Further, in another embodiment, the second gate trenches 12 may be dummy gate trenches. In this case, the gate electrodes 15 formed in the dummy gate trenches (second gate trenches 12) and the gate insulating films 14 formed in the dummy gate trenches (second gate trenches 12) are dummy (pseudo) gate electrodes and are dummy (pseudo) gate insulating films, respectively, and do not actually function. Since no power supply is connected to the dummy gate electrodes 15, no ON potential is applied to the dummy gate electrodes 15. Therefore, the dummy gate electrodes 15 are in a floating state. This configuration enables high-speed switching as compared with a case where the gate electrodes 15 formed in the second gate trenches 12 are not dummies, and accordingly achieves a reduction in switching loss.

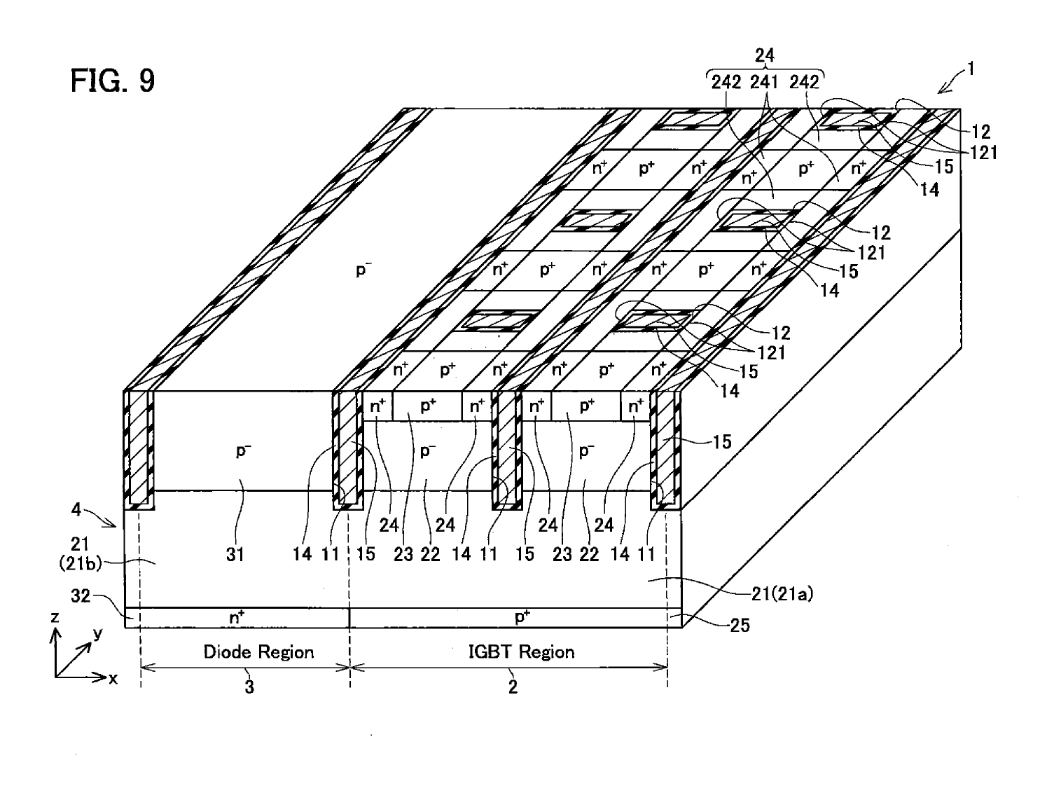

Further, in the embodiment described above, the first emitter layers 241 are continuously formed extending along the first gate trenches 11. However, this configuration does not imply any limitation. In another embodiment, as shown in FIG. 9, the first emitter layers 241 may be formed extending along the first gate trenches 11 and may be divided in a direction along the first gate trenches 11.

While specific examples of the present invention have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

Some of the aspects of the aforementioned embodiments may be listed below. In the above semiconductor device, the first gate trenches may extend longer than the second gate trenches. An emitter layer in the IGBT region may be formed so as to extend along the first gate trenches.

The emitter layer in the IGBT region may further include portions extending along the second gate trenches.

The second gate trenches may be dummy trenches, in which gate electrodes are formed and On potential is not applied to the gate electrodes of the dummy trenches.

What is claimed is:

1. A semiconductor device in which an IGBT region and a diode region adjoining each other are formed on a same substrate, the semiconductor device comprising:
a plurality of first gate trenches extending abreast in a first direction in the IGBT region; and
a plurality of second gate trenches extending abreast in a second direction intersecting the first direction,
wherein
the first gate trenches and the second gate trenches are not in contact with each other.

2. The semiconductor device according to claim 1, wherein
the first gate trenches extend longer than the second gate trenches, and
an emitter layer in the IGBT region is formed so as to extend along the first gate trenches.

3. The semiconductor device according to claim 2, wherein
the emitter layer in the IGBT region further includes portions extending along the second gate trenches.

4. The semiconductor device according to claim 1, wherein
the second gate trenches are dummy trenches, in which gate electrodes are formed, and
ON-potential is not applied to the gate electrodes of the dummy trenches.
